(19) United States
(12) Patent Application Publication
(10) Pub. No.: US 2025/0376762 A1
(43) Pub. Date: Dec. 11, 2025

(54) CYCLIC PLASMA AND THERMAL PROCESS TO IMPROVE PECVD TI SILICIDE DEPOSITION SELECTIVITY

(71) Applicant: Applied Materials, Inc., Santa Clara, CA (US)

(72) Inventors: Yiyang WAN, Sunnyvale, CA (US); Shumao ZHANG, San Jose, CA (US); Chih-Hsun HSU, Santa Clara, CA (US); Weifeng YE, San Jose, CA (US); Wei ZHANG, Elmsford, NY (US); Jiang LU, Milpitas, CA (US)

(21) Appl. No.: 19/208,337

(22) Filed: May 14, 2025

Related U.S. Application Data
(60) Provisional application No. 63/656,573, filed on Jun. 5, 2024.

(51) Int. Cl. C23C 16/42; C23C 16/14; C23C 16/505

(52) U.S. Cl. CPC C23C 16/42; C23C 16/14; C23C 16/505

(57) ABSTRACT

Embodiments of the present principles generally relate to forming low resistivity contacts for semiconductor device formation. In some embodiments, a method of forming a metal silicide layer on a surface of a contact structure includes depositing a first layer including a metal on a first surface that includes silicon and a second surface that includes a dielectric material by providing a carrier gas, a metal-containing precursor, and a hydrogen-containing precursor to a deposition chamber and applying an RF power while maintaining the substrate at a first temperature. The method includes delivering a gas mixture including titanium tetrachloride (TiCl₄) to the first surface and the second surface, while maintaining the substrate at the first temperature, to remove at least a portion of the deposited metal and cyclically repeating the metal deposition and the delivering the gas mixture processes to reach the desired thickness of the metal silicide layer.

### CROSS-REFERENCE TO RELATED APPLICATIONS

This application claims benefit of U.S. Provisional Patent Application Ser. No. 63/656,573, filed Jun. 5, 2024, which is herein incorporated by reference in its entirety.

### FIELD

Embodiments of the present principles generally relate to methods for forming low resistivity contacts for semiconductor device formation.

### BACKGROUND

Integrated circuits have evolved into complex devices that can include millions of transistors, capacitors, and resistors on a single chip. In the course of integrated circuit evolution, functional density (that is, the number of interconnected devices per chip area) has generally increased while geometry size (that is, the smallest component (or line) that can be created using a fabrication process) has decreased.

Microelectronic devices are fabricated on a semiconductor substrate as integrated circuits in which various conductive layers are interconnected with one another to permit electronic signals to propagate within the device. Examples of such devices include memory (for example, DRAM (dynamic random access memory)) and logic devices, including both planar and three-dimensional structures. Three-dimensional structures include finFET (fin field-effect transistor) or MOSFET (metal-oxide-semiconductor field-effect transistor) devices.

An example of a finFET or MOSFET device includes a gate electrode on a gate dielectric layer on a surface of a semiconductor substrate. Source/drain regions are provided along opposite sides of the gate electrode. The source and drain regions are generally heavily doped regions of the semiconductor substrate. Usually, a silicide layer, for example, a titanium silicide layer, is required to form a reliable contact at the formed source and drain regions.

In a traditional middle-end-of-the-line (MEOL) contact junction formation process, a feature also referred to as a cavity, a via, or a trench, is fabricated in the semiconductor substrate. MEOL contact junctions allow connections between front-end-of-the-line (FEOL) semiconductor structures and back-end-of-the-line (BEOL) interconnects. Contacts with a low resistivity are desirable in semiconductor devices. However, when MEOL contacts have high resistance, the contacts produce poor connections between the FEOL structures and the BEOL packaging interconnects, reducing the performance of the packaged semiconductor structures.

In traditional MEOL contact formation, a conformal titanium silicide (TiSi) layer is formed on a silicon or silicon germanium connection as a capping layer. However, conventional plasma enhanced-titanium (PE-Ti) deposition methods cannot meet the PE-Ti deposition on silicon (Si) to silicon nitride (SiN) selectivity requirements of next generation semiconductors. Conventional PE-Ti deposition can cause thick Ti deposits on the dielectric material (SiN) of trench sidewalls, requiring an additional wet etch procedure to remove the Ti deposit before a bottom-up trench/gap fill process can be performed.

There is at least a need for improved methods to increase Si to SiN selectivity for PE-Ti deposition.

### SUMMARY

Embodiments of the present principles generally relate to forming low resistivity contacts for semiconductor device formation. More particularly, embodiments described herein provide methods for forming TiSi capping layers with improved PE-Ti deposition selectivity for the production of MEOL contacts for semiconductor devices.

In some embodiments, a method of forming a metal silicide layer on a surface of a contact structure includes depositing a first layer including a metal by a plasma deposition process on a first surface and a second surface of a substrate. The first surface includes silicon, and the second surface includes a dielectric material. The method includes heating the first layer to an annealing temperature and cyclically repeating the first layer deposition process and the heating the first layer process at least one more time.

In some embodiments, a method of forming a metal silicide layer on a surface of a contact structure includes depositing a first layer including a metal by a plasma deposition process on a first surface and a second surface of a substrate. The first surface includes silicon, and the second surface includes a dielectric material. The method includes delivering a gas mixture including titanium tetrachloride (TiCl₄) to the first surface and the second surface to remove at least a portion of the deposited metal on the second surface of a substrate and cyclically repeating the first layer deposition process and the providing a gas mixture including titanium tetrachloride (TiCl₄) process at least one more time.

In some embodiments, a method of forming a metal silicide layer on a surface of a contact structure includes depositing a first layer including a metal on a first surface that includes silicon and a second surface that includes a dielectric material by providing a carrier gas, a metal-containing precursor, and a hydrogen-containing precursor to a deposition chamber and applying an RF power while maintaining the substrate at a first temperature. The method includes thermally annealing the first layer by providing argon to the deposition chamber while maintaining the substrate at the first temperature and cyclically repeating the metal deposition and thermal annealing processes to reach the desired thickness of the metal silicide layer.

In some embodiments, a method of forming a metal silicide layer on a surface of a contact structure includes depositing a first layer including a metal on a first surface that includes silicon and a second surface that includes a dielectric material by providing a carrier gas, a metal-containing precursor, and a hydrogen-containing precursor to a deposition chamber and applying an RF power while maintaining the first surface and the second surface at a first temperature. The method includes delivering a gas mixture including titanium tetrachloride (TiCl₄) to the first surface and the second surface, while maintaining the first surface and the second surface at the first temperature, to remove at least a portion of the deposited metal and cyclically repeating the metal deposition and the delivering the gas mixture processes to reach the desired thickness of the metal silicide layer.

In at least some embodiments, a method of forming a metal silicide layer on a surface of a contact structure includes providing a substrate into a process chamber, the substrate including a first surface that includes silicon and a second surface that includes a dielectric material. The method includes, flowing titanium tetrachloride (TiCl₄) into the process chamber at a first flowrate, flowing a hydrogen-containing precursor into the process chamber at a second flow rate, applying a power to the process chamber to ignite a plasma, and depositing a first layer including a metal onto the first surface and the second surface using the plasma. The method further includes stopping the flow of the hydrogen-containing precursor and the application of the power to the process chamber, and continuing the flow of TiCl₄ into the process chamber at a third flowrate to remove at least a portion of the first layer from the second surface.

### BRIEF DESCRIPTION OF THE DRAWINGS

Embodiments of the present principles, briefly summarized above and discussed in greater detail below, can be understood by reference to the illustrative embodiments of the principles depicted in the appended drawings. However, the appended drawings illustrate only typical embodiments of the principles and are thus not to be considered limiting of scope, for the principles may admit to other equally effective embodiments.

FIG. 1 is a cross-section view of a portion of a semiconductor structure, in accordance with some embodiments.

FIG. 2 is a method of forming middle-end-of-the-line contacts, in accordance with some embodiments.

FIG. 3A-E are cross-section views of a portion of a semiconductor structure, in accordance with some embodiments.

To facilitate understanding, identical reference numerals have been used, where possible, to designate identical elements that are common to the figures. The figures are not drawn to scale and may be simplified for clarity. Elements and features of one embodiment may be beneficially incorporated in other embodiments without further recitation.

### DETAILED DESCRIPTION

Embodiments of the present principles generally relate to forming low resistivity contacts for semiconductor device formation. More particularly, embodiments described herein provide methods for forming TiSi capping layers with improved plasma enhanced (PE)-Ti deposition selectivity for the production of MEOL contacts for semiconductor devices. It has been discovered that cyclic PE-Ti deposition methods described herein increase PE-Ti deposition on silicon (Si) containing contacts to deposition on a dielectric layer (e.g., silicon nitride (SIN)) selectivity. For example, some embodiments describe a cyclic PE-Ti method including a plasma deposition and thermal anneal process, whereas other embodiments describe a cyclic PE-Ti method including a plasma deposition and TiCl₄ soak process.

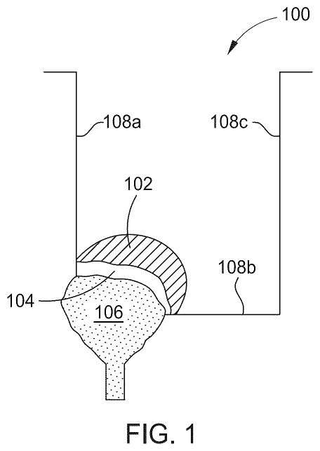

FIG. 1 is a schematic illustration of a structure having a tungsten layer disposed on a TiSi capping layer. As shown in FIG. 1, structure 100 has a tungsten layer 102 which has been selectively deposited on a TiSi capping layer 104. TiSi capping layer 104 is disposed on contact structure 106. Conventional methods for depositing the TiSi capping layer 104, such as PE-Ti deposition processes, can produce thick Ti deposits on dielectric surfaces 108a, 108b, and 108c. These Ti deposits are typically removed with a wet etch process before a bottom-up trench/gap fill operation can be performed, thus adding additional steps and cost to the production of the semiconductor device.

In contrast, the cyclic PE-Ti deposition methods of the present disclosure can provide an increased PE-Ti deposition on a Si containing surface to a SiN containing surface selectivity, reducing the buildup of Ti on the dielectric surfaces 108a, 108b, and 108c while a TiSi capping layer 104 is formed on/within the contact structure 106. In some embodiments, the cyclic PE-Ti deposition method involves a plasma deposition process and a thermal annealing process. In other embodiments, the cyclic PE-Ti deposition method involves a plasma deposition process and a TiCl₄ soak. Without being bound by theory, it is believed that a periodic annealing process cause Si to diffuse to the top of the formed TiSi layer which increases the speed and electrical characteristics of the formed TiSi layer in the next plasma cycle allowing more Ti to be deposited on the Si containing surface in comparison to the SiN containing surfaces, as the depositing rate of Ti on SiN is dependent on the length of the plasma treatment, whereas periodic TiCl₄ soaking steps increase Si to SiN deposition selectivity by etching the Ti deposition from SiN surface to reduce Ti layer build up thus improving overall deposition selectivity.

### Process Examples

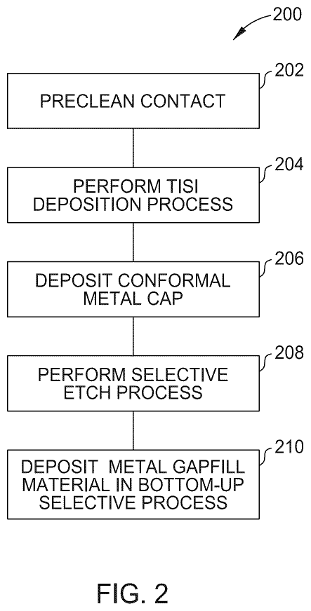

The methods of the present disclosure can be effective for metal gap fill processes in general and may be used with metal gap fill material such as, for example, tungsten, molybdenum, and the like. For the sake of brevity, examples discussed use tungsten but are not meant to be limited to only tungsten. In the method 200 of FIG. 2, a cyclic PE-Ti deposition is used to provide titanium silicide (TiSi) capping layers with an increased PE-Ti deposition on Si to SiN selectivity. The TiSi capping layers can be further capped with tungsten (W), molybdenum (Mo), cobalt (Co), ruthenium (Ru), or other metals.

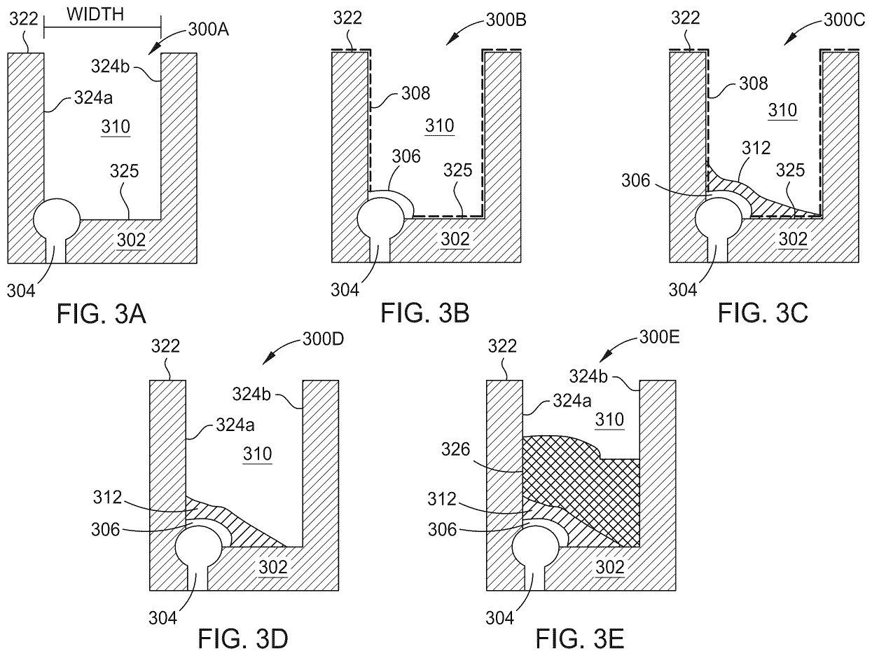

In the discussion of the method 200, references will be made to the views 300A-300E of FIGS. 3A-3E. In block 202, a preclean process is performed to remove any contaminants and/or oxidation from the surfaces of a contact structure as depicted in a view 300A of FIGS. 3A-3E. The contact structure has a silicon-based portion 304 that is exposed in a cavity 310 of a substrate 302 formed of a dielectric material (e.g., silicon nitride, silicon oxide, and silicon oxide carbide). In some embodiments, the silicon-based portion 304 may include a silicon (Si) material or a silicon germanium (SiGe) material.

In one or more embodiments, cavities (e.g., vias) can have an average width. For example, cavity 310 can have a width (shown in FIG. 3A) of about 35 nanometers (nm) or less, such as about 5 nm to about 35 nm, such as about 5 nm, 10 nm, and 15 nm to about 20 nm, 25 nm, 30 nm, or 35 nm. In one or more embodiments, cavity 310 can have an aspect ratio (depth:width) of about 1:1 to about 100:1, such as about 10:1, 15:1, or 25:1 to about 35:1, 45:1, or 50:1.

In block 204, a TiSi deposition process is performed using a cyclic PE-Ti deposition method to produce a TiSi layer 306 on the silicon-based portion 304 as depicted in a view 300B of FIG. 3B. The term titanium silicide (TiSi) as used herein can include titanium silicides that have a composition represented as TiₓSi_{y}, which may include Ti₅Si₃, TiSi₂, TiSi, or combinations thereof. In alternative embodiments, layer 306 is either of titanium or silicon. A thin TiSiN layer 308 may also form on the surfaces of the field 322 of the substrate 302 and on sidewalls 324a, 324b in the cavity 310, including a bottom surface 325 of the cavity 310. However, the cyclic PE-Ti deposition method increases deposition selectivity to the silicon-based portion 304 over the dielectric material of the substrate 302. In some embodiments, the cyclic PE-Ti deposition method involves a plasma deposition process and a thermal annealing process. In other embodiments, the cyclic PE-Ti deposition process involves a plasma deposition process and a TiCl₄ soak.

In one or more embodiments, the plasma deposition process is performed by introducing a hydrogen-containing precursor utilizing a conductively coupled plasma (CCP) deposition process. In one or more embodiments, the plasma deposition process includes introducing a hydrogen-containing precursor and a metal-containing precursor with the carrier gas. In one or more embodiments, the metal-containing precursor gas may be fluorine-free to prevent the formation of metal fluoride solids that have undesirable resistivity properties. The hydrogen-containing precursor can include molecular hydrogen (H₂), silane (SiH₄), disilane (Si₂H₆), or combinations thereof and the metal-containing precursor is titanium chloride (TiCl₄). The carrier gas may include a noble gas, such as argon (Ar), neon (Ne), helium (He), and combinations thereof. Without being bound by theory, the introduction of both the hydrogen-containing and the metal-containing precursors into the carrier gas causes both precursors to become energized on a molecular level to a point of at least partial dissociation in the carrier gas. For example, titanium chloride may disassociate into titanium-based ions (Ti⁺, TiClₓ⁺) or free radical titanium trichloride (TiCl₃^{·}); hydrogen may disassociate into hydronium ions (H⁺) or hydrogen free radicals (H*). The dissociated species may then interact with the silicon surface of the silicon-containing contact, donate electrons to the silicon atoms, and interact with one another to form the titanium silicide layer on the top of the silicon-based portion 304.

In one or more embodiment, the plasma deposition process is performed by providing TiCl₄ at a flowrate of about 5 sccm to about 100 sccm, H₂ at a flowrate of about 30 sccm to about 6,000 sccm, and argon at a flowrate of about 1.5 k sccm into a process chamber and operating the process chamber at an RF power of about 100 W to about 500 W, a RF frequency of about 350 kHz to about 13.56 MHz, a plus frequency of about 10 kHz, a duty cycle of about 10% to about 50%, and a pressure of about 3 Torr to about 10 Torr, for about 10 s to about 20 s. In one or more embodiments, the semiconductor substrate is maintained at a deposition temperature of about 300° C. to 550° C., such as about 300° C., 400° C., and 425° C. to about 475° C., 500° C., and 550° C. In one or more embodiments, TiCl₄ may be provided at a flowrate of about 10 sccm to about 100 sccm, such as about 15 sccm to about 100 sccm, about 20 sccm to about 100 sccm, about 50 sccm to about 100 sccm, or about 10 sccm to about 50 sccm. In one or more embodiments, H₂ may be provided at a flowrate of about 35 sccm to about 6,000 sccm, such as about 50 sccm to about 6,000 sccm, about 100 sccm to about 5,000 sccm, about 200 sccm to about 5,000 sccm, about 500 sccm to about 4,000 sccm, about 35 sccm to about 3,000 sccm, or about 50 sccm to about 1,000 sccm. In one or more embodiments, the process chamber may be operated at an RF power of about 150 W to about 500 W, such as about 150 W to about 250 W, about 250 W to about 500 W, or about 150 W to about 300 W. In one or more embodiments, the process chamber may be operated at a RF frequency of about 500 kHz to about 13.56 MHz, such as about 1 MHz to about 13.56 MHz, about 5 MHz to about 13.56 MHz, about 10 MHz to about 13.56 MHz, or about 1 MHz to about 10 MHz. In one or more embodiments, the process chamber may be operated at a duty cycle of about 20% to about 50%, such as about 30% to about 50%, or about 20% to about 30%. For example, in one embodiment, the plasma deposition is performed by providing TiCl₄ at a flowrate of about 15 sccm, H₂ at a flowrate of about 1,500 sccm, and argon at a flowrate of about 1.5 k sccm into a process chamber and operating the process chamber at a power of about 125 W, a RF frequency of about 350 KHz to about 13.56 MHz, a plus frequency of about 10 kHz, a duty cycle of about 25%, a pressure of about 3 Torr to about 10 Torr, and a temperature of about 425° C. to about 475° C.

In one or more embodiments, the plasma deposition process is followed by a thermal annealing process. The thermal aneling process is performed in the same process chamber as the plasma deposition process without a vacuum break (e.g., exposure to atmosphere). The thermal anneal process is performed by providing argon to the process chamber at a flowrate of about 100 sccm to about 4,000 sccm, such as about 500 sccm to about 3,000 sccm or about 1,000 sccm to about 2,000 sccm, and maintaining the substrate at a temperature of about 300° C. to 550° C., such as about 300° C., 400° C., and 425° C. to about 475° C., 500° C., and 550° C., for about 5 seconds(s) to about 20 s.

In one or more embodiments, the plasma deposition process and thermal annealing process are performed as a cyclic process, such that a first cycle includes a first plasma treatment process followed by a first thermal anneal process, a second cycle includes second plasma treatment process followed by a second thermal anneal process, a third cycle includes a third plasma treatment process followed by a third thermal anneal process, and so on. Any number of cycles may be performed to reach the desired and/or predetermined thickness of the TiSi capping layer. Longer anneal periods and more cycles provide better PE-Ti deposition on Si to SiN selectivity, and improved TiSi layer composition uniformity throughout the TiSi layer thickness. For example, a cyclic PE-Ti deposition method with four cycles of a 25 s plasma deposition process and a 10 s thermal anneal process had a 7% increase in PE-Ti deposition on Si to SiN selectivity compared to a 100 s PE-Ti plasma deposition process and a cyclic PE-Ti deposition method with eight cycles of a 12.5 s plasma deposition process and a 10 s thermal anneal process had a 16% increase in PE-Ti deposition on Si to SiN selectivity.

In one or more embodiments, the plasma deposition process is followed by a TiCl₄ soak. The TiCl₄ soak is performed in the same process chamber as the plasma deposition process without a vacuum break (e.g., exposure to atmosphere). The TiCl₄ soak is performed by providing TiCl₄ to the process chamber at a flowrate of about 10 sccm to about 50 sccm, such as about 25 sccm to 50 sccm or about 10 sccm to about 25 sccm, and maintaining the substrate at a temperature of about 300° C. to 550° C., such as about 300° C., 400° C., and 425° C. to about 475° C., 500° C., and 550° C., for about 5 s to about 20 s.

In at least some embodiments, the TiCl₄ soak is performed as a continuation of the plasma deposition process. For example, in at least some embodiments, TiCl₄, H₂, and Ar are flowed into the processing chamber. An RF power is applied to the process chamber to ignite a plasma, and a TiSi layer is deposited on the substrate. The RF power, the flow of H₂, and the flow of Ar are stopped after the deposition, while the flow of TiCl₄ is continued to remove at least a portion of the deposited Ti.

In one or more embodiments, the plasma deposition process and TiCl₄ soak process are performed as a cyclic process, such that a first cycle includes a first plasma treatment process followed by a first TiCl₄ soak step, a second cycle includes second plasma treatment process followed by a second TiCl₄ soak step, a third cycle includes a third plasma treatment process followed by a third TiCl₄ soak step, and so on. Any number of cycles may be performed to reach the desired and/or predetermined thickness of the TiSi capping layer. Longer TiCl₄ soak steps and more cycles provide better PE-Ti deposition on Si to SiN selectivity and improved TiSi layer composition uniformity throughout the TiSi layer thickness. For example, a cyclic PE-Ti deposition method with four cycles of a 25 s plasma deposition process and a 10 s TiCl₄ soak had a 9% increase in PE-Ti deposition on Si to SiN selectivity compared to a 100 s PE-Ti plasma deposition process.

In block 206, a metal cap 312 is deposited on the TiSi layer 306 on the silicon-based portion 304 as depicted in a view 300C of FIG. 3C. The metal cap 312 can be deposited by any suitable deposition process, such as CVD or ALD. In some embodiments, the metal cap 312 may be formed of tungsten. In some embodiments, the metal cap 312 may be formed of molybdenum. In some embodiments, for example, a metal cap provides metal seeding on a bottom of the cavity 310.

After deposition of the metal cap 312, a process may be used to perform a bottom-up gap fill (blocks 208, 210 of FIG. 2). For a bottom-up gap fill process, in block 210, a selective etch process (block 208) is optionally performed and is depicted in a view 300D of FIG. 3D.

In block 210, a metal gap fill material 326 is deposited in a bottom-up selective process (e.g., a tungsten hexafluoride (WF₆) based selective process (tungsten over dielectric material of the sidewalls 324a, 324b of the cavity 310, etc.)) as depicted in a view 300E of FIG. 3E. After an optional wet/dry pull-back (etch) of block 208, metal cap 312 remains at the bottom of the structure and on the silicon-based portion as shown in FIG. 3D, which provides a seed layer, for example, for a selective CVD W bottom-up gap fill. The metal gap fill material 326 is shown in contact with the metal cap 312 such that the metal gap fill material 326 is in electrical communication with the contact structure. The metal gap fill material 326 is also in contact with at least a portion of the sidewalls 324a, 324b.

Any suitable chemical deposition process, including but not limited to CVD or ALD processes, may be utilized for the metal gap fill material process 210. The metal gap fill material may be applied such that the material is deposited onto the bottom portion of the device feature and then grown upwards towards the semiconductor field region such that the resultant gap fill material at least approaches the field region (as shown in FIG. 3E) or is at least partially level with the field region (not shown).

The methods of the present disclosure may be performed in individual process chambers that may be provided as part of a cluster tool. In some embodiments, a processing chamber may be capable of performing an etch process, a cleaning process, an annealing process, a CVD deposition process, or an ALD deposition process. As used herein, CVD refers to chemical vapor deposition, and ALD refers to atomic layer deposition. In some embodiments, a processing chamber is a Selectra™ Etch chamber available from Applied Materials of Santa Clara, Calif. In some embodiments, a processing chamber is a SiCoNi™ Pre-clean chamber available from Applied Materials of Santa Clara, Calif. In some embodiments, a processing chamber may be a Centura™ Epi chamber, Volta™ CVD/ALD chamber, or Encore™ PVD chamber, all available from Applied Materials of Santa Clara, Calif.

Embodiments in accordance with the present principles may be implemented in hardware, firmware, software, or any combination thereof. Embodiments may also be implemented as instructions stored using one or more computer readable media, which may be read and executed by one or more processors. A computer readable medium may include any mechanism for storing or transmitting information in a form readable by a machine (e.g., a computing platform or a “virtual machine” running on one or more computing platforms). For example, a computer readable medium may include any suitable form of volatile or non-volatile memory. In some embodiments, the computer readable media may include a non-transitory computer readable medium.

Certain embodiments and features have been described using a set of numerical upper limits and a set of numerical lower limits. It should be appreciated that ranges including the combination of any two values, e.g., the combination of any lower value with any upper value, the combination of any two lower values, and/or the combination of any two upper values, are contemplated unless otherwise indicated. Certain lower limits, upper limits, and ranges appear in one or more claims below. All numerical values are “about” or “approximately” the indicated value, and take into account experimental error and variations that would be expected by a person having ordinary skill in the art.

Likewise whenever a composition, an element or a group of elements is preceded with the transitional phrase “comprising”, it is understood that we also contemplate the same composition or group of elements may be modified with other transitional phrases, such as “consisting essentially of,” “consisting of”, “selected from the group of consisting of,” or “is” preceding the recitation of the composition, element, or elements and vice versa. The phrases, unless otherwise specified, “consists essentially of” and “consisting essentially of” do not exclude the presence of other steps, elements, or materials, whether or not, specifically mentioned in this specification, so long as such steps, elements, or materials, do not affect the basic and novel characteristics of the claimed features, additionally, the phrases do not exclude impurities and variances normally associated with the elements and materials used.

While the foregoing is directed to embodiments of the present principles, other and further embodiments of the principles may be devised without departing from the basic scope thereof.

1. A method of forming a metal silicide layer on a surface of a contact structure comprising:
depositing a first layer comprising a metal by a plasma deposition process on a first surface and a second surface of a substrate, wherein the first surface comprises silicon and the second surface comprises a dielectric material;
delivering a gas mixture comprising titanium tetrachloride (TiCl₄) to the first surface and the second surface to remove at least a portion of the deposited metal on the second surface of the substrate; and
cyclically repeating the first layer deposition process and the delivering the gas mixture comprising TiCl₄ process at least one more time.

2. The method of claim 1, wherein the delivering the gas mixture comprising TiCl₄ process further comprises heating the substrate to a temperature of about 300° C. to about 550° C.

3. The method of claim 1, wherein the first layer deposition process is about 10 s to about 25 s.

4. The method of claim 1, wherein TiCl₄ is provided for about 5 s to about 20 s.

5. The method of claim 1, wherein the first layer deposition process and the delivering the gas mixture comprising TiCl₄ process are cyclically repeated four or more times.

6. The method of claim 1, wherein the metal comprises titanium.

7. The method of claim 1, further comprising depositing a metal cap on the first layer.

8. A method of forming a metal silicide layer on a surface of a contact structure comprising:
depositing a first layer comprising a metal on a first surface that comprises silicon and a second surface that comprises a dielectric material by providing a carrier gas, a metal-containing precursor, and a hydrogen-containing precursor to a deposition chamber and applying an RF power while maintaining the first surface and the second surface at a first temperature;
delivering a gas mixture comprising titanium tetrachloride (TiCl₄) to the first surface and the second surface, while maintaining the first surface and the second surface at the first temperature, to remove at least a portion of the deposited metal; and
cyclically repeating the first layer deposition process and the delivering the gas mixture process to reach a predetermined thickness of the metal silicide layer.

9. The method of claim 8, wherein the first temperature is about 300° C. to about 550° C.

10. The method of claim 8, wherein the carrier gas comprises argon, neon, helium, or combinations thereof.

11. The method of claim 8, wherein the metal-containing precursor comprises titanium chloride (TiCl₄), and the hydrogen-containing precursor comprises molecular hydrogen (H₂).

12. The method of claim 8, wherein the first layer deposition process is about 10 s to about 25 s, and the delivering the gas mixture process is about 5 s to about 20 s.

13. The method of claim 8, wherein the first layer deposition process and the delivering the gas mixture process are cyclically repeated at least four times.

14. The method of claim 8, wherein the delivering the gas mixture process comprises providing TiCl₄ at a flowrate of about 10 SCCM to about 50 SCCM and heating the substrate to a temperature of about 300° C. to about 550° C.

15. The method of claim 8, wherein the first layer deposition process and the delivering the gas mixture process are performed in the same process chamber.

16. A method of forming a metal silicide layer on a surface of a contact structure comprising:
providing a substrate into a process chamber, the substrate comprising a first surface that comprises silicon and a second surface that comprises a dielectric material;
flowing titanium tetrachloride (TiCl₄) into the process chamber at a first flowrate;
flowing a hydrogen-containing precursor into the process chamber at a second flow rate;
applying a power to the process chamber to ignite a plasma;
depositing a first layer comprising a metal onto the first surface and the second surface using the plasma;
stopping the flow of the hydrogen-containing precursor and the application of the power to the process chamber; and
continuing flowing TiCl₄ into the process chamber at a third flowrate to remove at least a portion of the first layer from the second surface.

17. The method of claim 16, wherein the first flowrate of TiCl₄ is about 5 sccm to about 100 sccm.

18. The method of claim 16, wherein the third flowrate of TiCl₄ is of about 10 sccm to about 50 sccm.

19. The method of claim 16, wherein the power is applied to the process chamber for about 10 s to about 20 s.

20. The method of claim 16, wherein TiCl₄ is flowed at the third flowrate for about 5 s to about 20 s.
